(19) United States
(12) Patent Application Publication
(10) Pub. No.: US 2022/0127137 A1
(43) Pub. Date: Apr. 28, 2022

(54) Sensor Arrangement and Method for Producing a Sensor Arrangement

(71) Applicant: TDK Corporation, Tokyo (JP)

(72) Inventor: Wolfgang Pahl, Munchen (DE)

(21) Appl. No.: 17/481,840

(22) Filed: Sep. 22, 2021

(30) Foreign Application Priority Data
Oct. 26, 2020 (DE) 102020128095.5

(51) Int. Cl. B81B 3/00; B81B 7/00; B81C 3/00

(52) U.S. Cl. CPC B81B 3/0067; B81B 7/0045; B81C 2203/037; B81B 2201/0257; B81C 3/001

(57) ABSTRACT

In an embodiment a sensor arrangement includes a substrate, at least one spacer arranged directly onto a surface of the substrate, wherein the spacer comprises a soft material and a sensor chip attached to the substrate by an adhesive, wherein both the at least one spacer and the adhesive are arranged at least partly between the sensor chip and the substrate, and wherein the spacer is adapted and arranged to define a bond line thickness of the adhesive.

### CROSS-REFERENCE TO RELATED APPLICATIONS

This application claims priority of German Patent Application No. 102020128095.5, filed on Oct. 26, 2020, which application is hereby incorporated herein by reference.

### TECHNICAL FIELD

The present invention relates to a sensor arrangement, in particular a MEMS sensor arrangement. Moreover, the present invention relates to a method for producing a sensor arrangement.

### BACKGROUND

MEMS (Micro Electronic Mechanical Systems) sensors, in particular MEMS microphones, are very sensitive to internal stress (e.g. from CTE (Coefficient of Thermal Expansion)) mismatch between sensor die and package materials) as well as to external stress (e.g. from second level assembly).

Such stress is not only critical on a destructive level, where irreversible damage occurs to the active components or their electrical interconnections, but already on much lower level, that just slightly and reversibly affects important electrical parameters like the acousto-electric transducer ratio, the so-called sensitivity.

It is common practice to use relatively soft die attach adhesives for mounting the sensor die onto its package substrate. To improve the stress decoupling, the height of this adhesive film, the so called bond line thickness (BLT), is often larger than for the assembly of conventional dies, and reaches, for example, around 30 μm.

Achieving such high BLTs is difficult in mass production, since the adhesive is applied as viscous paste that tends to flow and bleed before final curing, increasingly with the deposited amount. Due to miniaturization, the safety margins towards critical structures provided for soldering or wire bonding are tight and they do not tolerate any contamination, so that the spread of the adhesive may be limited to around 100 μm or even less, relating to the die edges.

This becomes further complicated due to viscosity variation over time and temperature. Moreover, the highly dynamic die placement with imperfect z axis and force control squeezes out a not well defined amount of the adhesive. All this results in poor control over the final BLT as well as the spread of the fillet.

One approach to solve this problem is the addition of spacer particles (e.g. glass spheres) to the adhesive. Their diameter should define the BLT. Such large particles have to be added to the viscous adhesive in a significant amount to statistically ensure a sufficient distribution over the die footprint.

This bears the risk of frequent clogging of the dispenser nozzle. Also, sedimentation occurs. Sophisticated deposition methods like jet dispensers cannot be applied. Screen or stencil printing cannot handle filler particles as big as the intended print layer thickness. Major disadvantage is that such spheres with adequate shape and precision are usually made from rather hard material such as glass. As consequence, the spacers can easily form stress bridges. That means, they act correctly in that they define the high BLT, but at the same time they fail to provide stress decoupling. The same holds true for elevations formed in the package substrate.

### SUMMARY

Embodiments solve the above mentioned problems.

According to a first embodiment of the present disclosure, a sensor arrangement is provided. The sensor arrangement may be a MEMS sensor arrangement. The sensor arrangement may be a MEMS microphone.

The sensor arrangement comprises a substrate. The substrate may comprise a multilayer laminate with metal contact patterns on top and bottom surface. The substrate may further comprise internal electrical interconnections. Additional layers like platings or solder masks may be integral parts of the substrate.

The sensor arrangement further comprises at least one spacer, for example exactly one spacer. The sensor arrangement can comprise a plurality of spacers, e.g. two, four, eight or 12 spacers, for example.

The spacer comprises a soft material. The material of the spacer is, in particular, softer than glass. The spacer may comprise a Shore A hardness between 15 and 80, preferably between 25 and 70. A Young's modulus of the at least one spacer may be between of 0.1 Mpa and 200 Mpa, preferably between 1 Mpa and 50 Mpa.

The at least one spacer is arranged directly onto a surface of the substrate, e.g. by means of conventional methods like printing or dispensing. In particular, no adhesive is arranged between the substrate and the spacer.

The sensor arrangement further comprises a sensor chip. The sensor chip is attached to the substrate, in particular to the surface of the substrate onto which the spacer is applied. The spacer is arranged—at least partly—between the substrate and the sensor chip.

The sensor chip is attached to the substrate by means of an adhesive. The adhesive may comprise a silicone material or similar materials. Alternatively, the adhesive may comprise a closed-cell polymer foam.

The adhesive is arranged between the substrate and the sensor chip. The adhesive acts as a bond line between the substrate and the sensor chip. The adhesive is applied to the substrate after application of the spacer onto the substrate. In other words, the spacer is not applied onto the surface of the substrate in combination with the adhesive but as individual component before adhesive is applied onto the substrate.

Both the at least one spacer and the adhesive are arranged at least partly between the sensor chip and the substrate. In some embodiments, the adhesive may be applied at least partially around the spacer. The adhesive may also be applied on parts of a surface of the spacer, i.e. it may be applied partially over the spacer.

The spacer impedes uncontrolled squeeze and flow of the adhesive during die attach (attaching of the sensor chip). The spacer is adapted and arranged to define a bond line thickness, i.e. a height, of the adhesive.

Due to the soft material, the spacer is easy to prepare and to process. By means of the soft spacer a predetermined and sufficiently high bond line thickness can be achieved in a simple and efficient way. The final BLT can be reliably controlled. Stress decoupling of the sensor arrangement can thus be ensured.

According to one embodiment, the at least one spacer comprises the same material or a material with similar elastic properties as the adhesive. For example, the spacer comprises a soft silicone, a soft epoxy, or a modified polycarbamin acid derivate.

Soft silicones are well suited for forming the spacer. Only drawback is the usually low adhesion of the adhesive on the silicone surface due to low surface energy. Because of the relatively small area of the spacer compared to the whole bonding area, this will not affect the mechanical strength of the bond too much. However, this effect can be avoided by selecting another material like soft epoxy or modified polycarbamin acid derivate, which are also well suited for forming the spacer.

According to one embodiment, the spacer comprises a material supporting UV, light or thermal curing. Alternatively, the spacer can comprise a solvent based material.

By using a material that supports light or UV curing spread can easily be stopped right after the deposition by suitable illumination, independently of the deposition method. But also thermally curable or even solvent based materials are appropriate, since only very little volume is required, so that the spread is limited. For the same reason, it is also possible to use material with a very high viscosity (e g. >100 Pa·s).

According to one embodiment, the spacer may comprise a height between 10 μm and 300 μm, preferably between 20 μm and 100 μm. In this way, a sufficiently high bond line can be guaranteed.

According to one embodiment, the at least one spacer is applied to the surface of the substrate in the form of at least one line. The spacer may comprise one continuous line. Alternatively, a plurality of spacers shaped as discrete lines may be provided. Alternatively, the spacer may comprise the form of a spherical element or bump.

The form of the spacer may be adapted to its material and/or the material of the adhesive. In this way, the desired bond line thickness of the adhesive can be reliably achieved.

According to a further embodiment, a method for producing a sensor arrangement is described. The sensor arrangement may be the previously described sensor arrangement. The sensor arrangement may be a MEMS microphone. All features described in connection with the sensor arrangement apply for the method and vice versa.

The method comprises the following steps:

A) Providing a substrate, in particular a MEMS packaging substrate. The substrate may be adequately dimensioned to produce a plurality, e.g. hundreds or thousands, of sensor arrangements. The substrate may comprise a multilayer laminate with metal contact patterns on top and bottom surface. The substrate may further comprise internal electrical interconnections. Additional layers like platings or solder masks may be integral parts of the substrate.

B) Providing a plurality of spacers and arranging the spacers onto a surface of the substrate. Before the spacers are arranged on the surface an optional height inspection (profile measurement) of the spacers may take place.

The spacers comprise a soft material, e.g. a soft silicone, a soft epoxy, or a modified polycarbamin acid derivate. The respective spacer may comprise a Shore A hardness between 15 and 80, preferably between 25 and 70. The respective spacer, in particular a material of the respective spacer, may comprise a Young's modulus between 0.1 Mpa and 200 Mpa, preferably between 1 Mpa and 50 Mpa.

The spacers are arranged in a predetermined pattern. At least one spacer is provided on the footprint for one respective sensor chip. A preferred spacer arrangement may consist of four laterally relatively small dots or bumps, the distance between two of them being typically larger than ⅓ of a length of a neighboring die edge.

The spacers may be printed onto the substrate. Alternatively, the spacers are applied onto the substrate by means of needle or jet dispensing. Due to the small dimension of the respective spacer a sufficient distance (e.g. 100 μm) between the dispenser and the surface of the substrate/spacer can be ensured. This may be relevant for dispensing of the adhesive.

C) Curing a material of the spacers. In particular, an UV, light or thermal curing of the spacers may take place. UV or light curing can be done for a plurality of spacers when applied in a parallel process like printing, or for each individual spacer immediately after deposition in case of a serial process like dispensing. Here, curing of a plurality of spacers is also an option.

D) Providing an adhesive and applying the adhesive. The respective spacer and the adhesive may comprise the same material or a material with similar elastic properties. The adhesive comprises a Shore A hardness between 15 and 80, preferably between 25 and 70. A Young's modulus of the adhesive is between 0.1 Mpa and 200 Mpa, preferably between 1 Mpa and 50 Mpa.

The adhesive is applied in a predetermined pattern. In particular, the adhesive is applied onto parts of the surface

such that—in the final sensor arrangement—the adhesive is arranged at least partly between the sensor chip and the substrate.

In one embodiment, adhesive may be applied at least partially over and/or around the spacers. In alternative embodiments, there may be a distance between the respective spacer and the adhesive. The adhesive is provided on the footprint for the respective sensor chip. The adhesive is applied by means of jet dispensing, screen printing or stencil printing, for example. Due to the small dimension of the respective spacer a sufficient distance (e.g. 100 μm) between the dispenser and the surface of the substrate/spacer is ensured.

E) Providing a plurality of sensor chips and attaching the sensor chips onto the substrate by means of the adhesive. The respective sensor chip is attached to the substrate such that at least one spacer is arranged between the respective sensor chip and the substrate.

F) Curing the adhesive.

G) Separating into individual components. In particular, the substrate is cut into a plurality of components such that a plurality of sensor arrangements each comprising at least one spacer is formed.

For arranging the spacers onto the substrate, conventional mass production methods (e.g. printing or jet dispensing) can be used. Furthermore, as the spacers are arranged onto the substrate before adhesive is applied, sophisticated adhesive deposition methods like jet dispensing can be used for applying the adhesive, as well. Clogging of the dispenser nozzle and/or sedimentation of spacer particles are avoided. Thus, an easy and reliable method for producing a sensor arrangement is provided.

Moreover, the needed BLT can be achieved in mass production, since the adhesive applied as viscous paste is efficiently prevented from flowing and bleeding before final curing by means of the soft spacers. In this way, an efficient method for producing a sensor arrangement is provided.

According to one embodiment, additional components are assembled before the separation into individual components (step G)) takes place. For example, an application-specific integrated circuit (ASIC) may be assembled. Furthermore, internal electrical connections, e.g. wire bonds, may be provided.

According to one embodiment, the method further comprises the step of providing and assembling a protection for the sensor arrangement before step G) takes place. In this step a cover of the respective sensor arrangement, e.g. a metal cap, may be provided and assembled.

### BRIEF DESCRIPTION OF THE DRAWINGS

Further features, refinements and expediencies become apparent from the following description of the exemplary embodiments in connection with the figures.

FIG. 1 schematically shows a top view of a part of a sensor arrangement;

FIG. 2 schematically shows a top view of a part of a sensor arrangement according to a first embodiment;

FIG. 3 schematically shows a top view of a part of a sensor arrangement according to a second embodiment;

FIG. 4 schematically shows a top view of a part of a sensor arrangement according to a third embodiment;

FIG. 5 schematically shows a top view of a part of a sensor arrangement according to a fourth embodiment;

FIG. 6 schematically shows a top view of a sensor arrangement; and

FIG. 7 schematically shows a sectional side of the sensor arrangement according to FIG. 6.

In the figures, elements of the same structure and/or functionality may be referenced by the same reference numerals. It is to be understood that the embodiments shown in the figures are illustrative representations and are not necessarily drawn to scale.

### DETAILED DESCRIPTION OF ILLUSTRATIVE EMBODIMENTS

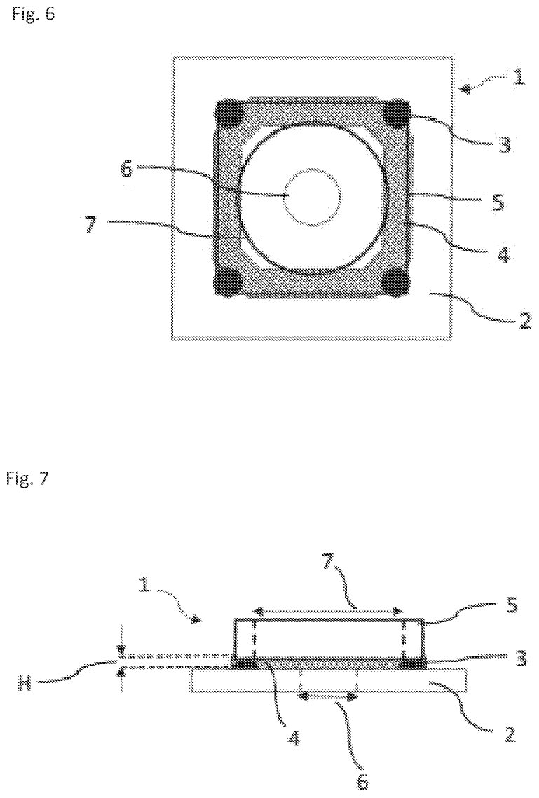

FIGS. 1 to 5 show parts of a sensor arrangement 1 in different embodiments. FIGS. 6 and 7 show a complete sensor arrangement 1 in a first embodiment.

The sensor arrangement 1 is a MEMS sensor arrangement. In particular, the sensor arrangement 1 is a MEMS microphone.

The sensor arrangement 1 comprises a substrate 2. The substrate 2 is square shaped. Of course, other shapes are also conceivable for the substrate 2. For example, the substrate 2 may be shaped rectangularly. The substrate 2 comprises a hole 6 which is adapted and arranged to serve as acoustic access for the microphone. The hole 6 is arranged in a central area of the substrate 2. The hole 6 completely penetrates the substrate 2, as can be gathered from FIG. 6, for example.

The sensor arrangement 1 further comprises a sensor chip 5 (see FIGS. 6 and 7). The sensor chip 5 comprises a cavity 7. The cavity 7 is arranged in a central region of the sensor chip 5. The cavity 7 may be an oval or circular or hexagonal hole which penetrates the sensor chip 5 completely. On an upper side of the sensor chip 5 (i.e. that side which is arranged furthest away from the substrate 2 once the sensor chip 5 is attached to the substrate 2), a membrane is attached to the sensor chip 5 for covering the cavity 7 (not explicitly shown).

The sensor chip 5 is attached to the substrate 2 by means of an adhesive 4. The adhesive 4 may comprise a silicone material or similar materials. Alternatively, the adhesive may comprise a closed-cell polymer foam. The adhesive 4 acts as a bond line between the substrate 2 and the sensor chip 5.

The adhesive 4 is applied to a surface of the substrate 2 in a predetermined pattern or geometry, which is adapted to a shape of the sensor chip 5 and, in particular, to a shape and size/diameter of the cavity 7. The adhesive 4 is applied to the substrate 2 such that the adhesive 4 does not or only slightly cover the cavity 7 in the sensor chip 5 (see FIG. 6). The adhesive 4 may be applied such that it covers an outer edge area of the sensor chip 5.

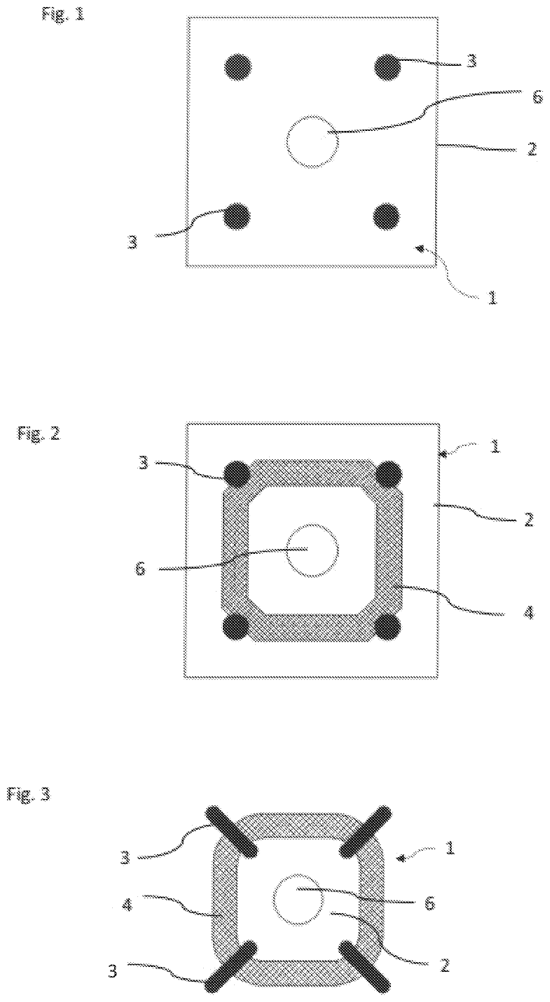

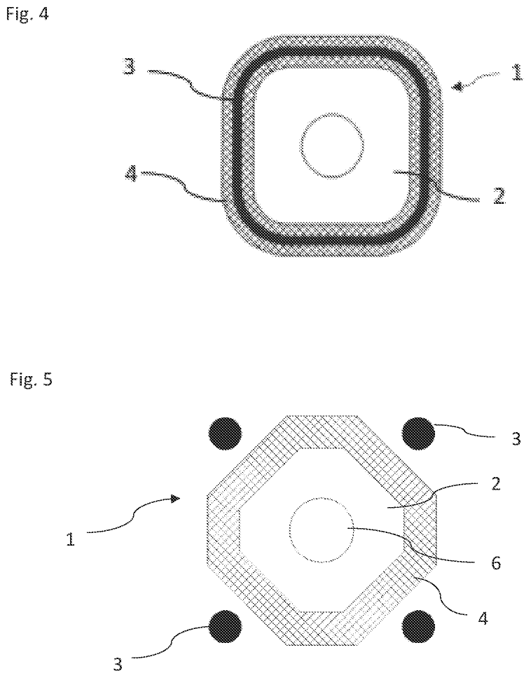

In the embodiments shown in FIGS. 3 and 4, the adhesive 4 is applied to the substrate in the shape of a square with rounded corners. Of course, alternative geometries are conceivable for the adhesive 4 which depend, for example, on the material of the adhesive and/or on the shape of the sensor chip 5. For example, the adhesive 4 may be applied in the shape of an Octagon (FIGS. 2, 5 and 6). Usually, the shape of the adhesive 4 is closed to achieve an air-tight seal.

Depending on the geometry of the bond line, it may be advantageous to select also non-silicone material as adhesive 4. The reason is the inappropriate Poisson's ratio of close to 0.5 for silicones. As a consequence, they can change their shape virtually not by compressibility or expandability, but only by transverse contraction. But the latter may be significantly inhibited by the aspect ratio of a wide and narrow bond gap, so the joint behaves tough even though a low modulus adhesive is used. In that case, the Poisson's ratio should be <0.49, preferably <0.48, more preferably <0.45, most preferably <0.42.

The sensor arrangement 1 comprises at least one spacer 3.

The respective spacer 3 defines a bond line thickness or height H of the adhesive 4. A sufficiently high bond line thickness H is needed to improve stress decoupling of the sensor arrangement 1. In this context, the bond line thickness H of the adhesive 4 denotes the expansion of the adhesive 4 perpendicular to the surface of the substrate 2 onto which the adhesive 4 is applied.

The respective spacer 3 has a height between 10 μm and 300 μm, preferably between 20 μm and 100 μm, for definition of the final bond line thickness. The application of the respective spacer 3 can be done by needle or jet dispensing, or by a printing method like stencil or screen printing, which is described later on in more detail.

The respective spacer 3 is arranged directly onto the substrate 2 before adhesive 4 is applied to the substrate 2, i.e. it is pre-applied to the substrate 2. In particular, the spacers 3 are applied on a surface, i.e. an upper surface, of the substrate 2. In this context, the upper surface of the substrate 2 denotes that surface which is arrange closest to the sensor chip 5 once the sensor chip 5 is attached to the substrate 2. The respective spacer 3 is applied on a footprint for the sensor chip 5. The respective spacer 3 may be at least partly surrounded with adhesive 4 (see, for example, FIG. 4).

In the embodiment shown in FIGS. 1, 2, 3, 5, 6 and 7, the sensor arrangement 1 comprises four spacers 3. The respective spacer 3 may comprise the form of a spherical segment or bump (FIGS. 1, 2, 5, 6 and 7). Alternatively, the respective spacer 3 can comprise the form of a short line (FIG. 3). The short lines can be aligned to the centre area of the substrate 2 (FIG. 3).

The sensor arrangement 1 can also comprise more than four spacers 3, e.g. six or eight spacers 3 (not explicitly shown). The sensor arrangement 1 can also comprise less than four spacers 3, e.g. one or two spacers 3 (see, for example, FIG. 4). For example, in the embodiment illustrated by FIG. 4, exactly one spacer 3 is applied to the substrate 2. The said spacer 3 comprises the form of a square with rounded corners. The single spacer 3 comprises a continuous line. In this embodiment, the line shaped spacer 3 is completely surrounded by adhesive 4.

The respective spacer 3 comprises a soft material. In this context a soft material is understood to be softer than glass material. The respective spacer 3 comprises the same material or a material with similar elastic properties as the adhesive 4. The respective spacer 3 comprises a material supporting UV, light or thermal curing. Alternatively, the spacer 3 can comprise a solvent based material. For example, the spacer 3 comprises a soft silicone, a soft epoxy, or a modified polycarbamin acid derivate.

The Young's modulus of the cured spacer material is in a range of 0.1 to 200 Mpa, preferably 1 to 50 Mpa. Such soft materials are frequently specified rather by Shore A hardness. The shore A hardness of the spacer material is in a range of 15 to 80, preferably 25 to 70.

By means of the soft profiled spacer 3, the final bond line thickness H of the adhesive 4 is controlled in a simple and effective way. Thus, stress decoupling for the sensor arrangement 1 is effectively ensured.

In the following a method for producing a sensor arrangement 1, in particular the previously described MEMS microphone, is described. The method comprises the following steps:

In a first step A) a substrate 2 is provided. The substrate 2 is a MEMS substrate. The substrate is adequately dimensioned to produce a plurality, e.g. hundreds or thousands, of sensor arrangements. The substrate may comprise a multilayer laminate with metal contact patterns on top and bottom surface. The substrate may further comprise internal electrical interconnections. Additional layers like platings or solder masks may be integral parts of the substrate.

In a second step B) a plurality of spacers 3 are provided. The spacers 3 comprise a soft material, e.g. a soft silicone, a soft epoxy, or a modified polycarbamin acid derivate.

Optionally, a height inspection (profile measurement) of the spacers 3 may take place.

Afterwards, the spacers 3 are arranged onto the surface of the substrate 2 in a predetermined geometry. The geometry depends on the design of the sensor chip 5, the design of the substrate 2, the material of the spacer 3, the material of the adhesive 4, and/or the desired height of the bond line. The spacers 3 are arranged on the surface of the substrate 2 in the form of bumps or lines, for example.

A preferred spacer arrangement may consist of four laterally relatively small dots or bumps, the distance between two of them being typically larger than ⅓ of a length of a neighboring die edge.

The spacers 3 can be printed onto the surface of the substrate, e.g. by stencil or screen printing. Alternatively, the spacers 3 can be applied onto the substrate 2 by means of needle or jet dispensing.

Printing methods are suitable, since package substrates for MEMS microphones typically comprise a plurality of individual units in a large panel that is separated at the end of the assembly, usually after covering the units with a plurality of caps. Therefore, a single printing step can form hundreds or thousands of spacers 3 of high homogeneity.

In a next step C) a UV, light or thermal curing step can take place for curing the spacer material.

By using a material for the spacers 3 that supports light or UV curing (complete or to a certain degree), the spread can easily be stopped right after the deposition by suitable illumination, independently of the deposition method (i.e. printing or dispensing). This UV or light curing can be done for a plurality of spacers 3 when applied in a parallel process like printing, or for each individual spacer 3 immediately after deposition in case of a serial process like dispensing. Here, curing of a plurality of spacers is also an option.

But also thermally curable or even solvent based materials are appropriate for the spacers 3, since only very little volume is required, so that the spread is limited. For the same reason, it is also possible to use material with a very high viscosity (e g. >100 Pa·s) without sacrificing process speed.

In a next step D) an adhesive 4 is provided. The adhesive 4 is applied onto parts of the surface of the substrate 2 such that the adhesive 4 is arranged at least partly between the sensor chip 5 and the substrate 2. Adhesive 4 may also be applied onto a surface of the respective spacer 3.

The adhesive 4 is applied in a predetermined pattern. The pattern depends on the design of the sensor chip 5, the material of the spacer 3, the material of the adhesive 4, and/or the desired height of the bond line. For applying the adhesive 4, conventional mass production methods such as jet dispensing, printing or dispensing are used.

The respective spacer 3 and the adhesive 4 may comprise the same material or a material with similar elastic properties. The adhesive 4 comprises a Shore A hardness between 15 and 80, preferably between 25 and 70. A Young's modulus of the adhesive is between 0.1 Mpa and 200 Mpa, preferably between 1 Mpa and 50 Mpa.

In a next step E) a plurality of sensor chips is provided. The sensor chips 5 are attached onto the substrate 2 by means of the adhesive 4. The sensor chips 5 can be placed relatively rough and fast without compromising the bond line thickness accurateness.

In a step F), the adhesive 4 is cured.

After curing the adhesive 4, additional components may be assembled before a separation into individual components (see step G)) takes place. For example, an ASIC may be assembled. In addition, internal electrical connections, e.g. wire bonds and/or a glob top application may be provided.

Furthermore, a protection for the sensor arrangement 1 is provided. For example, a cover of the respective sensor arrangement 1, e.g. a metal cap, is provided and assembled.

In a last step G) the substrate 2 comprising the spacers 3, the adhesive 4 and the sensor chips 5 is separated into individual components such that a plurality of sensor arrangements 1 each comprising at least one spacer 3 is formed.

Although the invention has been illustrated and described in detail by means of the preferred embodiment examples, the present invention is not restricted by the disclosed examples and other variations may be derived by the skilled person without exceeding the scope of protection of the invention

What is claimed is:

1. A sensor arrangement comprising:
a substrate;
at least one spacer arranged directly onto a surface of the substrate, wherein the spacer comprises a soft material; and
a sensor chip attached to the substrate by an adhesive,
wherein both the at least one spacer and the adhesive are arranged at least partly between the sensor chip and the substrate, and
wherein the spacer is adapted and arranged to define a bond line thickness of the adhesive.

2. The sensor arrangement according to claim 1, wherein the at least one spacer comprises the same material or a material with similar elastic properties as the adhesive.

3. The sensor arrangement according to claim 1, wherein the at least one spacer is arranged at the surface of the substrate in form of a line or in form of a bump.

4. The sensor arrangement according to claim 1, wherein the at least one spacer comprises a material supporting UV, light or thermal curing, or wherein the at least one spacer comprises a solvent based material.

5. The sensor arrangement according to claim 1, wherein the at least one spacer comprises a height between 20 μm and 100 μm, inclusive.

6. The sensor arrangement according to claim 1, wherein the at least one spacer comprises a Shore A hardness between 25 and 70, inclusive.

7. The sensor arrangement according to claim 1, wherein a Young's modulus of the at least one spacer is between 1 Mpa and 50 Mpa, inclusive.

8. The sensor arrangement according to claim 1, wherein the adhesive comprises a Shore A hardness between 25 and 70, inclusive, and/or a Young's modulus between 1 Mpa and 50 Mpa, inclusive.

9. The sensor arrangement according to claim 1, wherein a material of the spacer comprises a soft silicone, a soft epoxy, or a modified polycarbamin acid derivate.

10. The sensor arrangement according to claim 1, wherein the sensor arrangement is a MEMS microphone.

11. A method for producing a sensor arrangement, the method comprising:
providing a substrate;
providing a plurality of spacers and arranging the spacers onto a surface of the substrate in a predetermined pattern;
curing a material of the spacers;
providing an adhesive and applying the adhesive onto parts of the surface of the substrate;
providing a plurality of sensor chips and attaching the sensor chips onto the substrate by the adhesive;
curing the adhesive; and
separating the substrate into individual components such that the sensor arrangement comprising at least one spacer is formed.

12. The method according to claim 11, further comprising inspecting a height of the spacers before the spacers are arranged on the substrate.

13. The method according to claim 11, further comprising providing and assembling a protection for the sensor arrangement before separating the substrate.

14. The method according to claim 11, wherein the spacers are printed onto the substrate, or wherein the spacers are applied onto the substrate by needle or jet dispensing.

15. The method according to claim 11, wherein curing the material of the spacers comprises curing the material by UV, by light or by thermal curing.

16. The method according to claim 11, wherein the respective spacer is positioned on the surface of the substrate in form of a line or a bump.

17. The method according to claim 11, wherein the material of the respective spacer comprises a soft silicone, a soft epoxy, or a modified polycarbamin acid derivate.

18. The method according to claim 11, wherein the respective spacer comprises a Shore A hardness between 25 and 70, inclusive, and wherein a Young's modulus of the respective spacer is between 1 Mpa and 50 Mpa, inclusive.

19. The method according to claim 11, wherein the respective spacer comprises the same material or a material with similar elastic properties as the adhesive.

20. The method according to claim 11, wherein the adhesive comprises a Shore A hardness between 25 and 70, inclusive, and/or a Young's modulus between 1 Mpa and 50 Mpa, inclusive.
